(19) United States
(12) Patent Application Publication
(10) Pub. No.: US 2025/0137101 A1
(43) Pub. Date: May 1, 2025

(54) ALUMINUM ALLOY MEMBER FOR FORMING FLUORIDE COATING THEREON AND ALUMINUM ALLOY MEMBER HAVING FLUORIDE COATING

(71) Applicant: RESONAC CORPORATION, Tokyo (JP)

(72) Inventors: Katsumasa HIROSE, Tokyo (JP); Takeshi KANESHITA, Tokyo (JP); Isao MURASE, Tokyo (JP); Yu KUDO, Tokyo (JP)

(73) Assignee: RESONAC CORPORATION, Tokyo (JP)

(21) Appl. No.: 18/691,490

(22) PCT Filed: Sep. 13, 2022
(86) PCT No.: PCT/JP2022/034148

§ 371 Date: Mar. 13, 2024

(30) Foreign Application Priority Data
Sep. 15, 2021 (JP) 2021-150087

(51) Int. Cl. C22C 21/08; C23C 16/455

(52) U.S. Cl. CPC C22C 21/08; C23C 16/45565

(57) ABSTRACT

An aluminum alloy member (1) for forming a fluoride coating thereon is intended for use as a component of a semiconductor production apparatus. The composition of the aluminum alloy member includes Mg: 1.2 mass % to 4.5 mass % and Si: 0.2 mass % to 1.0 mass %, with the excess Mg concentration being 0.5 mass % or more.

### TECHNICAL FIELD

The present invention relates to an aluminum alloy member for forming a fluoride coating thereon and an aluminum alloy member having a fluoride coating. Both of them are designed for use as a component in a semiconductor production apparatus. It also relates to a method for producing the aluminum alloy member.

### BACKGROUND ART

As a material for a component, such as, e.g., a chamber, a susceptor, and a backing plate, which constitutes a semiconductor production apparatus, a stretched material or a cast material made of A5052 (Al—Mg alloy) or A6061 (Al—Mg—Si based alloy) aluminum alloy are often used. Generally, in a semiconductor production apparatus, such a member is used at high temperatures and in a corrosive gas atmosphere, such as, e.g., silane (SiH₄), fluorine gas, chlorine halogen gas, etc. Therefore, the surface of the member is subjected to an anodic oxidation treatment to form a hard anodic oxide coating thereon to improve the corrosion resistance of the member.

Japanese Unexamined Patent Application Publication No. 2003-119539 (Patent Document 1) discloses an aluminum alloy member with improved corrosion resistance, achieved by forming a composite coating on the surface of an aluminum alloy substrate. The composite coating is either a combination of a Ni—P plating coating and a fluoride passive coating or a combination of a sulfuric acid anode oxide coating and a fluoride passive coating. In the aluminum alloy substrate, the contents of Si and Mg, and the contents of Fe, Cu, Mn, Cr, Zn, and Ni as impurity elements, are controlled within predetermined respective ranges.

International Publication No. 2020/008704 (Patent Document 2) and International Publication No. 2020/213307 (Patent Document 3) disclose an aluminum alloy member for forming a fluoride coating excellent in corrosion resistance to corrosive gases and plasma on a surface thereof. In the aluminum alloy member, the Si, Mg, and Fe contents are regulated within predetermined respective ranges, and the average crystal grain diameter in the member and the average major diameter of a Fe-based crystallized substance in the member are further regulated to satisfy a predetermined relational expression.

Japanese Unexamined Patent Application Publication No. H09-176772 (Patent Document 4) and No. H08-92684 (Patent Document 5) disclose an aluminum alloy member for forming a fluorinated passive coating with excellent corrosion resistance thereon. In the aluminum alloy member, the contents of Mg, Zr, Ti, and B are regulated within predetermined respective ranges.

### PRIOR ART DOCUMENT

### Patent Document

Patent Document 1: Japanese Unexamined Patent Application Publication No. 2003-119539
Patent Document 2: International Publication No. WO 2020/008704
Patent Document 3: International Publication No. WO 2020/213307
Patent Document 4: Japanese Unexamined Patent Application Publication No. H09-176772
Patent Document 5: Japanese Unexamined Patent Application Publication No. H08-92684

### SUMMARY OF THE INVENTION

### Problems to be Solved by the Invention

In general, when a fluoride coating is formed on the surface of an aluminum alloy member as a substrate by subjecting the surface to a fluoridation treatment, black spot-like ridges (hereinafter also referred to as “black spots”) may occur on the surface of the fluoride coating. When black spots occur, the fluoride coating cracks, leading to the coating peeling off. This results in the presence of impurity particles and a decrease in the corrosion resistance of the member.

With regard to the black spots, Patent Documents 2 and 3 described above disclose a schematic cross-sectional view illustrating the black spot generating area 111 and its surrounding area in an aluminum alloy substrate 100, as shown in FIG. 7. In the normal section 110 where no black spots have occurred, a magnesium fluoride (MgF₂) layer 101 and an aluminum fluoride (AlF₃) layer 102 are laminated on the surface of the aluminum alloy substrate 100 in the order described here to form a corrosion resistance coating. In contrast, in the black spot generating site 111, there are sites on the surface of the aluminum alloy substrate 100 where the magnesium fluoride layer has not been formed locally (defective sites; fractured sites). In these defective sites, aluminum fluoride growth is significant, leading to elevations considered the black spot generating site 111.

Further, in the case where the aluminum alloy member is intended for use as a component of a semiconductor production apparatus, it undergoes machining (e.g., cutting process) to conform to the shape of the semiconductor production apparatus prior to undergoing fluoridation treatment. Therefore, an aluminum alloy member is required to have excellent machining properties, i.e., high machinability.

The present invention has been made in view of the technical background described above. The purpose of the present invention is to provide an aluminum alloy member capable of forming a fluoride coating with few black spots on its surface, which has high machinability and excellent corrosion resistance, as well as an aluminum alloy member having the above-described fluoride coating and a production method thereof.

Other objects and advantages of the present invention will be apparent from the following preferred embodiments.

### Means for Solving the Problems

The present invention provides the following means.

1) An aluminum alloy member for forming a fluoride coating thereon, the aluminum alloy member being designed for use as a component in a semiconductor production apparatus, a composition of the aluminum alloy member comprising:
Mg: 1.2 mass % to 4.5 mass %; and
Si: 0.2 mass % to 1.0 mass %,
wherein an excess Mg concentration is 0.5 mass % or more.

2) The aluminum alloy member for forming a fluoride coating thereon, as recited in the above-described Item 1,
wherein the composition further comprises
Cu: 0.40 mass % or less,
Fe: 0.7% or less,
Mn: 0.15 mass % or less,
Cr: 0.35 mass % or less, and
the balance being Al and inevitable impurities.

3) An aluminum alloy member having a fluoride coating on a surface thereof, the aluminum alloy member being designed for use as a component in a semiconductor production apparatus, a composition of the aluminum alloy member comprising:
Mg: 1.2 mass % to 4.5 mass %; and
Si: 0.2 mass % to 1.0 mass %, and
wherein an excess Mg concentration is 0.5 mass % or more.

4) The aluminum alloy member having a fluoride coating, as recited in the above-described Item 3,
wherein the composition further comprises
Cu: 0.40 mass % or less,
Fe: 0.7% or less,
Mn: 0.15 mass % or less,
Cr: 0.35 mass % or less, and
the balance being Al and inevitable impurities.

5) The aluminum alloy member having a fluoride coating, as recited in the above-described Item 3 or 4,
wherein a surface Mg concentration is 4.0 mass % or more.

6) A method for producing an aluminum alloy member having a fluoride coating thereon, comprising:
sequentially subjecting at least a part of a surface of the aluminum alloy member as recited in the above-described Item 1 or 2 to an anodic oxide coating formation treatment and a fluoridation treatment.

### Effects of the Invention

The present invention achieves the following effects.

In the above-described Item 1, since the composition of the aluminum alloy member for forming a fluoride coating is set within a predetermined range, the member has high machinability. Therefore, the member can be well machined into the shape of the member for the semiconductor production apparatus.

Furthermore, when a fluoride coating is formed on the surface of the member as a substrate, its surface Mg concentration is increased, thereby reducing the number of occurrences of black spots. Therefore, in the case where the aluminum alloy member having the acquired fluoride coating is used as a member of a semiconductor production apparatus, the member exhibits excellent corrosion resistance to corrosive gases and plasma during semiconductor production, and the generation of impurity particles can be suppressed.

In the above-descried Item 2, the effects of the above-described Item 1 can be assuredly achieved.

In the above-described Item 3, then aluminum alloy member having a fluoride coating has a fluoride coating formed on the surface of the aluminum alloy member for forming a fluoride coating whose composition is set within a predetermined range. Therefore, the number of occurrences of black spots is reduced. For this reason, the member exhibits excellent corrosion resistance to corrosive gases and plasma during the semiconductor production process and suppresses the generation of impurity particles.

In the above-descried Item 4, the effects of the above-described Item 3 can be assuredly achieved.

In the above-described Item 5, the surface Mg concentration of the aluminum alloy member having the fluoride coating is 4.0 mass % or more, and therefore, the number of occurrences of black spots can be assuredly reduced. Therefore, the corrosion resistance of the member can be assuredly increased, and the generation of impurity particles can be assuredly suppressed.

In the above-described Item 6, an aluminum alloy member having a fluoride coating capable of exhibiting excellent corrosion resistance can be assuredly produced.

### BRIEF DESCRIPTION OF THE DRAWINGS

FIG. 1 is a schematic cross-sectional view of an aluminum alloy member for forming a fluoride coating thereon according to one embodiment of the present invention.

FIG. 2 is a schematic cross-sectional view of an aluminum alloy member having a fluoride coating according to an embodiment.

FIG. 3 is a schematic perspective view of a shower head, which is one example of an aluminum alloy member having a fluoride coating according to this embodiment.

FIG. 4 is a diagram (graph) showing the relation between the Mg concentration and the Si concentration in the aluminum alloy members of each Example and each Comparative Example.

FIG. 5 is a diagram (graph) showing the relation between the excess Mg concentration and the surface Mg concentration.

FIG. 6 is a diagram (graph) showing the relation between the excess Mg concentration and the number of occurrences of black spots.

FIG. 7 is a schematic cross-sectional diagram showing a black spot occurrence portion and its surrounding portion in a case where a black spot has occurred when forming a fluoride coating on the surface of an aluminum alloy member as a substrate.

### EMBODIMENTS FOR CARRYING OUT THE INVENTION

One embodiment of the present invention will be described below with reference to the drawings.

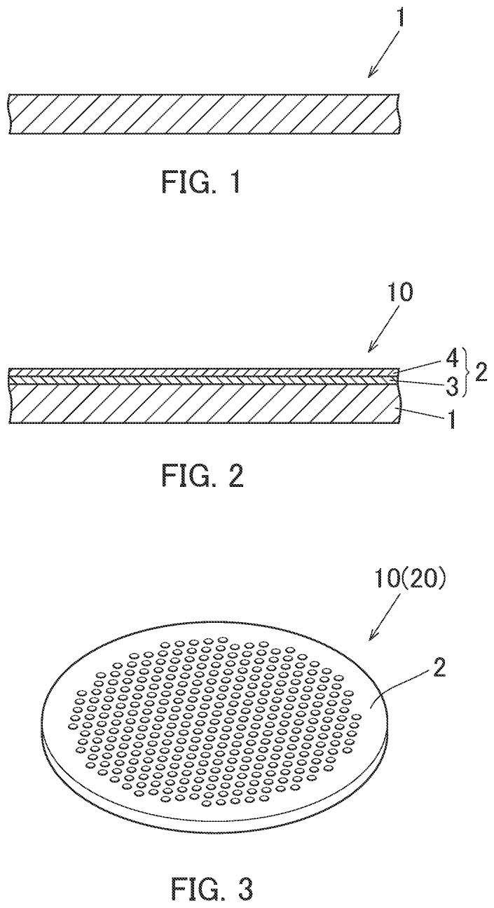

As shown in FIG. 1, the aluminum alloy member 1 for forming a fluoride coating thereon according to one embodiment of the present invention is designed for use as a member (including parts) in a semiconductor production apparatus, and has a composition comprising:
Mg: 1.2 mass % to 4.5 mass %; and
Si: 0.2 mass % to 1.0 mass %,
wherein an excess Mg concentration is 0.5 mass % or more.

By forming a fluoride coating on the surface of the member 1 serving as a substrate, an aluminum alloy member 10 having a fluoride coating 2 is obtained, as shown in FIG. 2. In this embodiment, the fluoride coating 2 is composed of a first coating layer 3 formed on the surface of the member 1 and a second coating layer 4 formed on the first coating layer 3.

The first coating layer 3 is a layer containing magnesium fluoride (MgF₂) (hereinafter also referred to as “magnesium fluoride layer”). The second coating layer 4 is a layer containing aluminum fluoride and aluminum oxide.

The thickness of the first coating layer 3 is not limited but is preferably from 0.1 μm to 5.0 μm. The thickness of the second coating layer 4 is not limited but is preferably from 0.1 μm to 10 μm.

It is generally known that Mg in an aluminum alloy diffuses and concentrates on the surface when heated. In this embodiment, Mg in the aluminum alloy member 1 diffuses to its surface due to the fluoridation treatment, and the magnesium fluoride layer (first coating layer 3) described above is formed by the reaction of this diffused Mg with fluorine.

Next, the composition (additive elements) of the aluminum alloy member 1 for forming a fluoride coating will be described below.

Si produces Mg₂Si (magnesium silicide), which is an intermetallic compound of Mg and Si in the Al matrix and can enhance the mechanical strength of the aluminum alloy member 1.

The Si concentration (i.e., Si content rate) of the aluminum alloy member 1 is set within the range of 0.2 mass % to 1.0 mass %. When the Si concentration is less than 0.2 mass %, the amount of Mg₂Si formed is low, causing burrs, surface cracks, and swellings during the cutting process and other machining, which results in poor machinability. When the Si concentration exceeds 1.0 mass % in the range in which the Mg concentration (i.e., Mg content rate) is 1.2 mass % to 4.5 mass %, according to thermodynamic equilibrium calculations, crystallized substances of Si alone are easily formed when the solution processing temperature is lower than or equal to 545° C. or the cooling rate during the quenching treatment after the solution treatment is slower than 0.5° C./s. When crystallized substances of Si alone are formed, SiF4 is formed and sublimates during the fluoridation treatment, which inhibits the formation of a uniform fluoride coating on the surface of the aluminum alloy member 1. To suppress the formation of such a crystallized substance of Si alone, the Si concentration is regulated to be 1.0 mass % or less.

Mg generates Mg₂Si in the Al matrix and can improve the mechanical strength of the aluminum alloy member 1. Mg diffuses from the inside of the aluminum alloy member 1 to its surface due to the fluoridation treatment and reacts with fluorine to form a dense magnesium fluoride layer as the first coating layer 3 on the surface of the aluminum alloy member 1.

The Mg concentration of the aluminum alloy member 1 is set to fall within the range of 1.2 mass % to 4.5 mass %. When the Mg concentration is less than 1.2 mass %, a dense magnesium fluoride layer cannot be formed, and black spots tend to occur easily. On the other hand, when the Mg concentration exceeds 4.5 mass %, the deformation resistance of the material increases, resulting in poor hot formability in the rolling process, extrusion process, and forging process, and aluminum alloys with a high Mg content of 5% or more are not used in practical applications.

The excess Mg concentration is determined by the Mg concentration and the Si concentration of the aluminum alloy member 1 and means the Mg concentration exceeding the stoichiometric composition ratio of Mg₂Si, Mg:Si=2:1, which is specifically calculated by the following formula. Note that in the following Formula 1, the units of elemental concentrations described in [ ] are all “mass %.”

[Excess Mg concentration]=[Mg concentration in the alloy]−1.73×[Si concentration in the alloy] (Formula 1).

Note that the upper limit of the excess Mg concentration is 4.15 mass % (i.e., in the case of Mg: 4.5 mass %, and Si: 0.2 mass %).

As described above, the aluminum alloy member 1 for forming a fluoride coating thereon according to this embodiment has a composition comprising:
Mg: 1.2 to 4.5 mass %, and
Si: 0.2 to 1.0 mass %,
wherein an excess Mg concentration is 0.5 mass % or more.

Therefore, the machinability (e.g., cutting workability) of the member 1 can be enhanced by the formation of Mg₂Si. Therefore, the member 1 can be favorably machined into the shape of the member of the semiconductor production apparatus prior to the fluoridation treatment.

Furthermore, when the surface of the aluminum alloy member 1 as a substrate is subjected to a fluoridation treatment, a uniform fluoride coating 2 is formed on the surface, specifically, the number of occurrences of black spots per square meter on the surface of the fluoride coating 2 can be reduced to less than 10. Therefore, in the case where the aluminum alloy member 10 having the fluoride coating 2 is used as a member of a semiconductor production apparatus, the member 10 exhibits excellent corrosion resistance to corrosive gases, plasma, etc., during the semiconductor production, and the generation of impurity particles can also be suppressed.

Among the additive elements in the composition of the aluminum alloy member 1, additive elements other than the above-mentioned Mg and Si and their concentrations are not limited. However, it is particularly preferred that the composition of the member 1 contains Cu: 0.40 mass % or less, Fe: 0.7 mass % or less, Mn: 0.15 mass % or less, and Cr: 0.35 mass % or less as additive elements other than the above-mentioned Mg and Si, and the balance being Al and inevitable impurities. With this, the member 1 can assuredly achieve the effects described above.

As the semiconductor production apparatuses described above, a CVD equipment, a PVD equipment, a dry etching equipment, a vacuum deposition equipment, and the like, can be exemplified. As the member, although not particularly limited, for example, a shower head 20 shown in FIG. 3, as well as other components such as a vacuum chamber, a susceptor, a backing plate, and the like, can be exemplified.

Note that the shower head 20 is a disk-shaped aluminum alloy member 10 having a fluoride coating 2 with a large number of through-holes formed in the direction of its thickness.

The aluminum alloy member 10 having a fluoride coating 2 is preferably 4.0 mass % or more in its surface Mg concentration. In this case, the number of occurrences of black spots can be assuredly reduced. Therefore, the corrosion resistance of the member 10 can be assuredly increased, and the generation of impurity particles can be assuredly suppressed.

In the aluminum alloy member 10 having the fluoride coating 2, Mg is present in the form of Mg₂Si and in the form of a solid solution Mg dissolved in Al, and the surface Mg concentration is determined by the amount of Mg₂Si and the amount of the solid solution Mg.

Next, the composition (additive elements) of the aluminum alloy member 1 for forming a fluoride coating thereon will be described below. Note that the aluminum alloy member for forming a fluoride coating thereon according to the present invention is not limited to those produced by the following production method.

### Casting Step

An aluminum alloy molten metal is prepared so that it has a composition including Mg: 1.2 to 4.5 mass %, Si: 0.2 to 1.0 mass %, and excess Mg concentration: 0.5 mass % or more, and the molten metal is cast and processed to obtain an ingot (a cast sheet, a billet, etc.). The casting method is not particularly limited. Specifically, a continuous casting rolling method, a hot top casting method, a float casting method, a semi-continuous casting method (DC casting method), etc., can be exemplified.

### Homogenization Heat Treatment Step

The resulting ingot is subjected to a homogenization heat treatment. The preferred processing conditions are a heat treatment temperature of 450° C. to 580° C. and a heat treatment time of 5 hours to 10 hours. The heat treatment temperature of 450° C. or higher ensures that the ingot is assuredly softened to reliably reduce the working pressure during the hot working, thus reliably improving the appearance quality and the productivity of the member 1. A heat treatment temperature of 580° C. or lower ensures that local melting inside the ingot is suppressed.

### Hot Working Step

The ingot after the homogenization heat treatment is subjected to hot working as a processing material to obtain a processed product. Although not specifically limited, the hot working is specifically exemplified by rolling processing, extrusion processing, forging processing, and other processing. The heating temperature of the ingot (processing material) during the hot working is preferably 450° C. to 550° C.

### Solution Treatment Step

The resulting work product (rolled product, extruded product, forged product, etc.) is subjected to a solution treatment by heating, followed by a quenching treatment. The solution treatment is performed to dissolve solute atoms (Si, Mg, etc.) into the aluminum alloy base matrix to form a uniform concentration distribution of solute atoms, i.e., a uniform solid solution. The quenching treatment is performed to rapidly cool the solid solution state obtained by the solution treatment to form a supersaturated solid solution state.

The cooling rate of the solution processing temperature and that of the quenching treatment are not particularly limited, but the solution processing temperature is preferably above 545° C. and/or the cooling rate of the quenching treatment is 0.5° C./s or higher. In this case, a solid solution state can be assuredly formed for the solute atoms. The subsequent artificial aging treatment generates sufficient Mg₂Si, which contributes to mechanical strength, thereby resulting in an improved mechanical strength of the member 1. Further, the formation of a crystallized substance of Si alone can be suppressed assuredly. Therefore, a uniform fluoride coating 2 can be assuredly formed on the surface of the member 1 during the fluoridation treatment.

Further, it is particularly preferred that the solution treatment temperature be between 550° C. and 580° C. and the processing time be between 2 hours and 6 hours. In this case, Mg₂Si can be assuredly solid-solutioned. Further, the quenching treatment may be selected from water cooling, hot water cooling, mist water cooling, fan water cooling, and discharge cooling.

### Artificial Aging Treatment Step

An artificial aging treatment is performed on the work piece after the solution treatment (including a quenching treatment). The processing conditions are preferably 170° C. to 210° C. in aging temperature and 5 hours to 11 hours in aging time. This ensures a reliable formation of Mg₂Si to ensure that the necessary strength for machining can be obtained.

### Machining Step

The work piece after the artificial aging treatment is machined to the shape and dimensions of the member of the semiconductor production apparatus using a machining equipment, thereby obtaining the aluminum alloy member 1 for forming the fluoride coating thereon as described above.

The machining is performed, for example, by cutting process using a cutting machine (milling machine, lathe machine, etc.) as a machining device.

Next, one example of a production method for an aluminum alloy member 10 having a fluoride coating 2 thereon will be described below. Note that the aluminum alloy member having a fluoride coating thereon according to the present invention is not limited to those produced by the following production method.

### Anode Oxide Coating Forming Processing Step

An anode oxide coating is formed on the surface of the aluminum alloy member 1 for forming a fluoride coating thereon as described above. The electrolyte used in this processing is not particularly limited, but a sulfuric acid aqueous solution can be exemplified. Further, the anode oxidation processing is preferably performed by controlling the temperature of the electrolytic bath (electrolyte) in the range of 10° C. to 40° C. The voltage for the anode oxidation is not particularly limited but is preferably set in the range of 10 V to 100 V. Further, the anode oxidation processing time is not particularly limited but is preferably set in the range of 1 min to 60 min.

### Fluoridation Treatment Processing Step

The surface of the aluminum alloy member 1 after forming the anode oxide coating described above is subjected to a fluoridation treatment. Specifically, the aluminum alloy member 1 after the anode oxide coating formation is set in a chamber, and the chamber is evacuated. Then, a gas containing a fluorine gas (e.g., fluorine-containing inert gas) is introduced into the chamber, the member 1 is heated in this fluorine gas atmosphere to thereby form a fluoride coating 2 on the surface of the member 1. The heating temperature in the fluorine gas atmosphere is preferably set in the range of 250° C. to 350° C. In this way, an aluminum alloy member 10 having a fluoride coating 2 is obtained.

In the fluoridation treatment processing step, in the case where the aluminum alloy member 10 having the fluoride coating 2 is used, for example, as a component of a vacuum chamber, a production method may be employed in which a fluoride coating 2 is reproduced and thickened on the surface of the aluminum alloy member 10 each time the inside of the vacuum chamber is cleaned using a fluorine gas.

Alternatively, for example, in a state in which the aluminum alloy member 1 machined into the shape of a shower head is set to a semiconductor production facility, the fluoride coating 2 may be formed on the surface of the aluminum alloy member 1 by heating the member 1 in a fluorine gas atmosphere, or the fluoride coating 2 may be formed using plasma.

Although an embodiment of the present invention has been described above, the present invention is not limited to the above embodiment but can be modified in various ways without departing from the gist of the present invention.

### EXAMPLES

Specific examples of the present invention are provided below. It should be noted, however, that the present invention is not limited to these examples.

### Example 1

An aluminum alloy (excess Mg concentration: 0.82 mass %) having a composition comprising: Si: 0.22 mass %, Mg: 1.20 mass %, Cu: 0.20 mass %, Fe: 0.07 mass %, Mn: 0.02 mass %, Cr: 0.05 mass %, and the balance being Al and inevitable impurities was heated to obtain an aluminum alloy molten metal, and then a 200 mm-thick plate ingot was produced by a DC casting method. Note that the excess Mg concentration was calculated according to Formula 1 described above.

Subsequently, the ingot was heated at a heat treatment temperature of 470° C. for 7 hours to perform a homogenization heat treatment. The ingot was then cut to a specified size, hot rolled at a processing temperature of 500° C., and then cold rolled at room temperature to obtain a 4 mm thick aluminum alloy sheet. Thereafter, the aluminum alloy sheet was cut into 50 mm (length)×50 mm (width) pieces, solution treated at 550° C. for 4 hours, water quenched, and then artificially aged at 180° C. for 8 hours.

Next, the aluminum alloy sheet after the artificial aging treatment was cut (specifically, performed turning processing) to the shape and dimensions of the member of the semiconductor production apparatus using a lathe machine. The processing conditions at that time were a cutting rate of 200 m/min and a feed rate of 0.5 mm/rev. Thus, a disk-shaped aluminum alloy member (its dimensions: 45 mm in diameter×4 mm in thickness) was obtained for forming a fluoride coating thereon.

Then, an anodic oxidation treatment was performed on the aluminum alloy member for forming a fluoride coating thereon by using a sulfuric acid solution with a concentration of 15 mass % as an electrolyte, controlling the temperature of the electrolyte bath (electrolyte) to 25° C., and applying a voltage of 20 V for 2 minutes to form a 2-μm-thick anodic oxide coating on the entire surface of the aluminum alloy member.

Next, the aluminum alloy member after forming an anode oxide coating was set in the chamber, and the chamber was evacuated. After that, a fluorine-containing inert gas was introduced into the chamber. In this state, the member was retained at a heating temperature of 260° C. for 24 hours to form a fluoride coating of 2 μm thickness on the entire surface of the member.

By the above-described production method, an aluminum alloy member 10 having the fluoride coating 2 thereon shown in FIG. 2 was obtained.

In the resulting member 10, the fluoride coating 2 had a configuration composed of a first coating layer containing magnesium fluoride (thickness: 0.5 μm) 3 formed on the surface of the aluminum alloy member 1 for forming the fluoride coating, and a second coating layer containing aluminum fluoride and aluminum oxide (thickness: 1.5 μm) formed on the first coating layer 3.

### Examples 2 to 16

An aluminum alloy member for forming a fluoride coating thereon was obtained in the same manner as in Example 1, except that instead of the aluminum alloy member of Example 1, an aluminum alloy member having a composition comprising Si, Mg, Cu, Fe, Mn, and Cr in the concentrations shown in Table 1 and the balance being Al and inevitable impurities was used, and then an aluminum alloy member having a fluoride coating was obtained in the same manner as in Example 1.

### Comparative Examples 1 to 5

An aluminum alloy member for forming a fluoride coating thereon was obtained in the same manner as in Example 1, except that instead of the aluminum alloy member of Example 1, an aluminum alloy member having a composition comprising Si, Mg, Cu, Fe, Mn, and Cr in the concentrations shown in Table 1 and the balance being Al and inevitable impurities was used, and then an aluminum alloy member having a fluoride coating was obtained in the same manner as in Example 1.

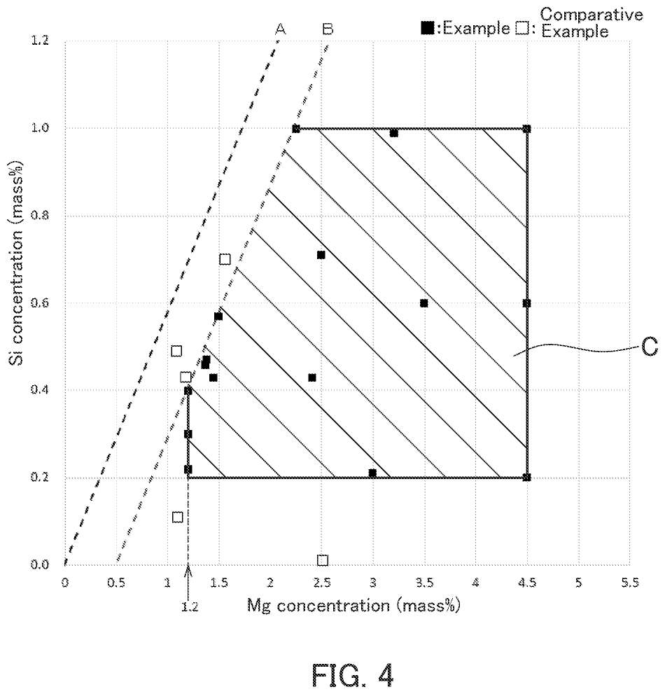

The Mg concentration (horizontal axis) and the Si concentration (vertical axis) in the aluminum alloy members of each Example and each Comparative Example are plotted in FIG. 4.

Note that in the figure, “▪” represents an Example and “□” represents a Comparative Example, the dashed line “A” indicates the balanced composition line for Mg₂Si content, and the dashed line “B” indicates the line for an excess Mg concentration of 0.5 mass %. The shaded region “C” indicates a region in the composition of the aluminum alloy member in which the Mg concentration is 1.2 to 4.5 mass %, Si is 0.2 to 1.0 mass %, and the excess Mg concentration is 0.5 mass % or more.

These aluminum alloy members were evaluated by examining the machinability, the number of occurrences of black spots, and the surface Mg concentration based on the following evaluation method. The results are shown in Table 1.

TABLE 1

| | | | | | | The number of | | | |
|---|---|---|---|---|---|---|---|---|---|
| | Aluminum alloy composition (mass %) | | | | | occurrences of | | Surface Mg | |
| | | | Excess | Other elements' | | black spots and | | concentration and its | |
| | Mg | Si | Mg | concentrations | Machinability | their evaluation | | evaluation (Mass %) | |
| Ex. 1 | 1.20 | 0.22 | 0.82 | Cu: 0.15-0.40 | ∘ | 5 | ∘ | 4.78 | ∘ |
| Ex. 2 | 1.20 | 0.40 | 0.51 | Fe: 0.7 or less | ∘ | 9 | ∘ | 4.03 | ∘ |
| Ex. 3 | 1.20 | 0.30 | 0.68 | Mn: 0.15 or less | ∘ | 7 | ∘ | 4.52 | ∘ |
| Ex. 4 | 1.37 | 0.46 | 0.57 | Cr: 0.04-0.35 | ∘ | 6 | ∘ | 4.01 | ∘ |
| Ex. 5 | 1.38 | 0.47 | 0.57 | | ∘ | 8 | ∘ | 4.24 | ∘ |
| Ex. 6 | 1.45 | 0.43 | 0.71 | | ∘ | 5 | ∘ | 4.69 | ∘ |
| Ex. 7 | 1.50 | 0.57 | 0.51 | | ∘ | 8 | ∘ | 4.05 | ∘ |
| Ex. 8 | 2.41 | 0.43 | 1.67 | | ∘ | 5 | ∘ | 6.81 | ∘ |
| Ex. 9 | 3.00 | 0.21 | 2.64 | | ∘ | 3 | ∘ | 8.24 | ∘ |
| Ex. 10 | 2.50 | 0.71 | 1.27 | | ∘ | 4 | ∘ | 5.76 | ∘ |
| Ex. 11 | 3.50 | 0.60 | 2.46 | | ∘ | 3 | ∘ | 8.10 | ∘ |
| Ex. 12 | 4.50 | 0.20 | 4.15 | | ∘ | 0 | ∘ | 10.51 | ∘ |
| Ex. 13 | 4.50 | 0.60 | 3.46 | | ∘ | 2 | ∘ | 9.24 | ∘ |
| Ex. 14 | 2.25 | 1.00 | 0.52 | | ∘ | 7 | ∘ | 4.20 | ∘ |
| Ex. 15 | 3.20 | 0.99 | 1.49 | | ∘ | 4 | ∘ | 6.50 | ∘ |
| Ex. 16 | 4.50 | 1.00 | 2.77 | | ∘ | 3 | ∘ | 8.65 | ∘ |
| Com. Ex. 1 | 1.56 | 0.70 | 0.35 | | ∘ | 63 | x | 3.74 | x |
| Com. Ex. 2 | 1.09 | 0.49 | 0.24 | | ∘ | 92 | x | 3.58 | x |
| Com. Ex. 3 | 1.18 | 0.43 | 0.44 | | ∘ | 40 | x | 3.95 | x |
| Com. Ex. 4 | 1.01 | 0.11 | 0.91 | | x | 4 | ∘ | 4.86 | ∘ |
| Com. Ex. 5 | 2.51 | 0.01 | 2.49 | | x | 3 | ∘ | 8.15 | ∘ |

### <Evaluation Method>

### Evaluation of Machinability

The aluminum alloy members after the artificial aging treatment (before forming the fluoride coating) were cut using a cutting machine (milling machine and lathe machine) to examine whether the members suffered from burrs, surface cracks, warpage, or other machining defects and/or deformation. The “∘” mark indicates that the material could be cut successfully without causing defects or deformation, and the “x” mark indicates that defects or deformation occurred, and the material could not be cut successfully.

### Evaluation of Number of Occurrences of Black Spots

The number of occurrences of black spots with a diameter of 50 μm or more visible on the entire surface of the fluoride coating on the aluminum alloy member having the fluoride coating was visually examined. The case in which the number of occurrences of black spots per square meter was less than 10 was marked as “∘,” and the case in which the number of occurrences of black spots per square meter was 10 or more was marked as “x.”

### Surface Mg Concentration Evaluation

The Mg concentration in the surface layer region from the surface to a depth of about 10 μm of the fluoride coating on the aluminum alloy member was measured by quantitative analysis using X-ray fluorescence spectrometry (XRF) as the surface Mg concentration. The quantification of the surface Mg concentration by the quantitative analysis was performed by a calibration curve method. Then, a surface Mg concentration of 4.0 mass % or more was designated as “∘,” and a surface Mg concentration of less than 4.0 mass % was designated as “x.”

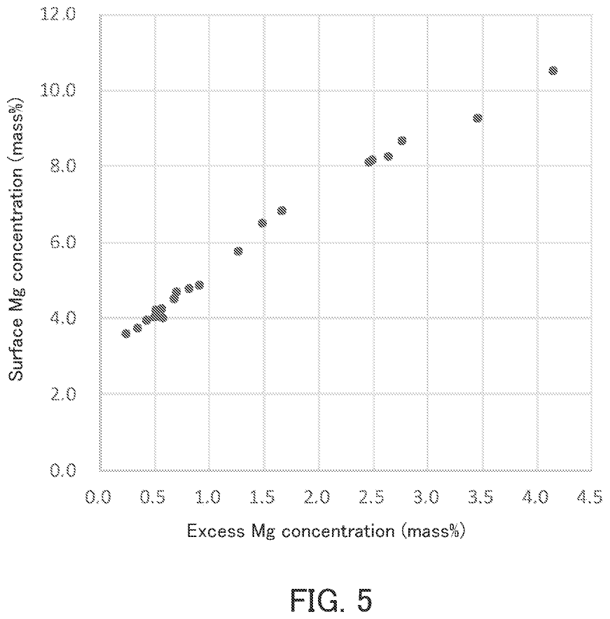

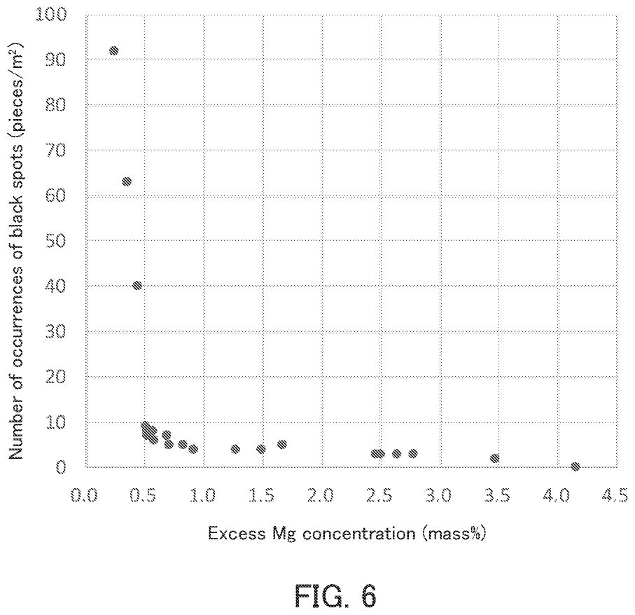

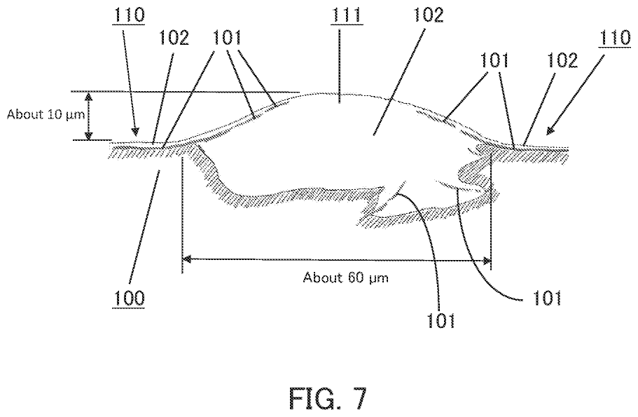

The relation between the excess Mg concentration and the surface Mg concentration is shown in FIG. 5. Further, the relation between the excess Mg concentration and the number of occurrences of black spots is shown in FIG. 6.

As shown in FIG. 5, the excess Mg concentration and the surface Mg concentration are generally positively correlated, i.e., the surface Mg concentration increases as the excess Mg concentration increases.

As shown in FIG. 6, there is a generally negative correlation between the excess Mg concentration and the number of occurrences of black spots. In other words, the number of occurrences of black spots decreases as the excess Mg concentration increases, and in particular, when the excess Mg concentration is 0.5 mass % or higher, it is confirmed that the number of occurrences of black spots is significantly reduced.

As shown in Table 1, it was confirmed that the aluminum alloy members of Examples 1 to 16 all have high machinability.

This application claims priority to Japanese Patent Application No. 2021-150087, filed on Sep. 15, 2021, the disclosure of which is incorporated herein by reference in its entirety.

It must be recognized that the terms and expressions used herein are for illustrative purposes only, are not to be construed as limiting, do not exclude any equivalents of the features shown and described herein, and allow for various variations within the claimed scope of this invention. It must be recognized that the present invention does not exclude any equivalents of the features shown and described herein, but permits various variations within the claimed scope of the invention.

### INDUSTRIAL APPLICABILITY

The present invention is applicable to an aluminum alloy member designed for forming a fluoride coating thereon and intended for use as a member (shower head, chamber, susceptor, backing plate, etc.) of a semiconductor production apparatus (CVD device, PVD device, dry etching device, vacuum deposition device, etc.). It also is applicable to an aluminum alloy member having a fluoride coating and a production method thereof.

### DESCRIPTION OF REFERENCE SYMBOLS

1: Aluminum alloy member for forming a fluoride coating thereon
2: Fluoride coating
3: First coating layer
4: Second coating layer
10: Aluminum alloy member having a fluoride coating
20: Shower head

1. An aluminum alloy member for forming a fluoride coating thereon, the aluminum alloy member being designed for use as a component in a semiconductor production apparatus, a composition of the aluminum alloy member comprising:
Mg: 1.2 mass % to 4.5 mass %; and
Si: 0.2 mass % to 1.0 mass %,
wherein an excess Mg concentration is 0.5 mass % or more.

2. The aluminum alloy member for forming a fluoride coating thereon, as recited in claim 1,
wherein the composition further comprises
Cu: 0.40 mass % or less,
Fe: 0.7% or less,
Mn: 0.15 mass % or less,
Cr: 0.35 mass % or less, and
the balance being Al and inevitable impurities.

3. An aluminum alloy member having a fluoride coating on a surface thereof, the aluminum alloy member being designed for use as a component in a semiconductor production apparatus, a composition of the aluminum alloy member comprising:
Mg: 1.2 mass % to 4.5 mass %; and
Si: 0.2 mass % to 1.0 mass %,
wherein an excess Mg concentration is 0.5 mass % or more.

4. The aluminum alloy member having a fluoride coating, as recited in claim 3,
wherein the composition further comprises
Cu: 0.40 mass % or less,
Fe: 0.7% or less,
Mn: 0.15 mass % or less,
Cr: 0.35 mass % or less, and
the balance being Al and inevitable impurities.

5. The aluminum alloy member having a fluoride coating, as recited in claim 3,
wherein a surface Mg concentration is 4.0 mass % or more.

6. A method for producing an aluminum alloy member having a fluoride coating thereon, comprising:
sequentially subjecting at least a part of a surface of the aluminum alloy member as recited in claim 1 to an anodic oxide coating formation treatment and a fluoridation treatment.
